(19) United States
(12) Patent Application Publication
(10) Pub. No.: US 2003/0190424 A1
(43) Pub. Date: Oct. 9, 2003

(54) Process for tungsten silicide atomic layer deposition

(76) Inventor: Ofer Sneh, Broomfield, CO (US)

Correspondence Address: WILSON SONSINI GOODRICH & ROSATI, 650 PAGE MILL ROAD, PALO ALTO, CA, 943041050

(21) Appl. No.: 10/052,890

(22) Filed: Oct. 19, 2001

Related U.S. Application Data
(60) Provisional application No. 60/242,033, filed on Oct. 20, 2000.

(51) Int. Cl. C23C 16/00

(52) U.S. Cl. 427/255.392; 427/255.393

(57) ABSTRACT

A method for growing a thin tungsten silicide film on a hydrated substrate in a reaction space introduces a tungsten halide precursor, where the halide is not fluorine, into the reaction space to the hydrated substrate to create, for example, a chlorine terminated substrate surface and deposit tungsten without scavenging silicon. A silicon hydride precursor is then introduced into the reaction space to the chloride terminated substrate surface to create a hydride terminated substrate surface and deposit silicon. The two preceding steps are repeated an integral number of times to form a tungsten silicide film on the substrate, wherein a reaction by-product is a hydrogen halide.

### CROSS-REFERENCE TO RELATED APPLICATIONS

This application claims the benefit of priority to U.S. Provisional Application No.: 60/242,033, filed Oct. 20, 2000 which is incorporated by reference in its entirety.

### BACKGROUND

1. Field of the Invention

The present invention relates generally to atomic layer deposition, and more particularly to a method for depositing tungsten silicide films with control over stoichiometry.

2. Description of the Related Art

In the manufacture of integrated circuits, deposition of thin films of many pure and compound materials is necessary, and many techniques have been developed to accomplish such depositions. In recent years the dominant technique for deposition of thin films in the art has been chemical vapor deposition (CVD), which has proven to have superior ability to provide uniform even coatings, and to coat relatively conformally into vias and over other high-aspect ratio and uneven features in wafer topology. As device density has continued to increase and geometry has become more complicated, even the superior conformal coating of CVD techniques has been challenged, and new and better techniques are needed.

The approach of a variant of CVD, Atomic Layer Deposition (ALD) has been considered for improvement in uniformity and conformality, especially for low temperature deposition.

CVD of tungsten silicide (WSiₓ) is conventionally applied in the industry of semiconductor wafer processing using WF₆ as the source for tungsten. In addition to putting down the tungsten this chemical has the ability to remove silicon by creating the volatile species SiF₄. As a result, achieving tungsten silicide CVD films was limited to certain conditions of high silicon precursor to WF₆ ratios and relatively high temperatures. Lower temperatures and lower silicon precursor to WF₆ ratios were deemed to result in low-silicon silicide films or W metal films. Accordingly, the problems of stoichiometry and deposition of high W stoichiometries was more pronounced if lower deposition rates were desired in order to achieve better conformality or improved film purity at interfaces with polysilicon. The chemistry of WF₆ with any given silicon precursor could only yield silicide if the thermodynamically favored generation of SiF₄ species was suppressed by the kinetics of the CVD process.

ALD represents an extreme case of CVD in which kinetics is taken out of being a factor and thermodynamics completely takes control. Accordingly, SiF₄ elimination of silicon cannot be suppressed. Therefore, WF₆ is not suitable for tungsten silicide ALD. In contrast to WF₆ , WCl₆ was not popular for tungsten based material deposition due to its much lower vapor pressure at room temperature.

However, the deposition per cycle for ALD processes is determined by the thermodynamics of the surfaces involved and does not necessarily guarantee to achieve the stoichiometry one desires. Accordingly, at given temperature and silicon precursor being used, the W deposition may deposit x fractional (less than 1) monolayer of W and the silicon deposition may deposit y fractional monolayer of silicon. The stoichiometry of silicide that can be realized are WₙₓSi_{my} where n and m are integers.

In practicality, the deposition per cycle of each element depends on the substrate and therefore the numbers n and m are actually more convoluted (for example, the density of W—Cl on the surface may vary depending on the W:Si ratio on the surface). However, the basic idea of stoichiometry being determined in discrete amounts of W and Si holds.

If ALD of WSiₓ is realized at high temperatures the deposition per cycle, i.e. x and y are smaller following the usual trend of surfaces needing less surface species to be thermodynamically stable. This trend reduces the density of ALD reactive sites and reduces deposition per cycle. Accordingly, the flexibility of tailoring the silicide increases since the combination nx:my has smaller steps. An additional degree of tunability can be realized by alternating the usage of several silicon precursors. Since the deposition per cycle depends on the nature of the saturating surface ligands the usage of several different silicon precursors adds flexibility because every precursor is likely to have different deposition per cycle, y, z, q and stoichiometry can be fine tuned further WₙₓSi_{my+lz+kq . . .} . Additionally, temperature dependence of the deposition per cycle is not similar for x, y, z, q, etc. Therefore, deposition temperature adds additional fine tuning knob to refine the final stoichiometry.

In the field of CVD a process ALD has emerged as a promising candidate to extend the abilities of CVD techniques, and is under rapid development by semiconductor equipment manufacturers to further improve characteristics of chemical vapor deposition. ALD is a process originally termed Atomic Layer Epitaxy, for which a competent reference is: Atomic Layer Epitaxy, edited by T. Suntola and M. Simpson, published by Blackie, Glasgo and London in 1990. This publication is incorporated herein by reference.

Generally ALD is a process wherein conventional CVD processes are divided into single-monolayer deposition steps, wherein each separate deposition step theoretically goes to saturation at a single molecular or atomic monolayer thickness, and self-terminates.

The deposition is the outcome of chemical reactions between reactive molecular precursors and the substrate. In similarity to CVD, elements composing the film are delivered as molecular precursors. The net reaction must deposit the pure desired film and eliminate the “extra” atoms that compose the molecular precursors (ligands). In the case of CVD the molecular precursors are fed simultaneously into the CVD reactor. A substrate is kept at temperature that is optimized to promote chemical reaction between the molecular precursors concurrent with efficient desorption of byproducts. Accordingly, the reaction proceeds to deposit the desired pure film.

For ALD applications, the molecular precursors are introduced into the ALD reactor separately. This is practically done by flowing one precursor at a time, i.e. a metal precursor—MLₓ (M=Al, W, Ta, Si etc.) that contains a metal element—M which is bonded to atomic or molecular ligands—L to make a volatile molecule. The metal precursor reaction is typically followed by inert gas purging to eliminate this precursor from the chamber prior to the separate introduction of the other precursor. An ALD reaction will take place only if the surface is prepared to react directly with the molecular precursor. Accordingly the surface is typically prepared to include hydrogen-containing ligands—AH that are reactive with the metal precursor. Surface—molecule reactions can proceed to react with all the ligands on the surface and deposit a monolayer of the metal with its passivating ligand: substrate—AH+MLₓ→substrate—AML_{y}+HL, where HL is the exchange reaction by-product. During the reaction the initial surface ligands—AH are consumed and the surface becomes covered with L ligands, that cannot further react with the metal precursor—MLₓ. Therefore, the reaction self-saturates when all the initial ligands are replaced with—ML_{y} species.

After completing the metal precursor reaction the excess precursor is typically removed from the reactor prior to the introduction of another precursor. The second type of precursor is used to restore the surface reactivity towards the metal precursor, i.e. eliminating the L ligands and redepositing AH ligands.

Most ALD processes have been applied to deposit compound films. In this case the second precursor is composed of a desired (usually nonmetallic) element—A (i.e. O, N, S), and hydrogen using, for example H₂O, NH₃, or H₂S. The reaction:—ML+AH_{z}→—M—AH+HL (for the sake of simplicity the chemical reactions are not balanced) converts the surface back to be AH-covered. The desired additional element—A is deposited and the ligands L are eliminated as volatile by-product. Again, the reaction consumes the reactive sites (this time the L terminated sites) and self-saturates when the reactive sites are entirely depleted.

The sequence of surface reactions that restores the surface to the initial point is called the ALD deposition cycle. Restoration to the initial surface is a keystone of ALD. It implies that films can be layered down in equal metered sequences that are all identical in chemical kinetics, deposition per cycle, composition and thickness. Self-saturating surface reactions make ALD insensitive to transport nonuniformity either from flow engineering or surface topography (i.e. deposition into high aspect ratio structures). Non-uniform flux can only result in different completion time at different areas. However, if each of the reactions is allowed to complete on the entire area, the different completion kinetics bear no penalty.

There is a need to provide processes which use WL₆ where L is a halogen other than F, as the cornerstone of WSiₓ ALD. There is a further need to utilize ALD to facilitate well-controlled submonolayer deposition and determine the stoichiometry of deposited films. There is yet another need to provide WSiₓ ALD formation by sequences of submonolayer deposition of W and Si to create the bulk silicide material.

### SUMMARY

Accordingly, an object of the present invention is to provide a method of growing a thin tungsten silicide film on a substrate in a reaction space.

Another object of the present invention is to provide methods utilizing WL₆, where L is a halogen other than F, as the cornerstone of WSiₓ ALD.

Yet another object of the present invention is to provide methods of WSiₓ ALD formation by using sequences of submonolayer deposition of W and Si to create the bulk silicide material.

A further object of the present invention is to provide methods which utilize ALD to facilitate well-controlled submonolayer deposition of tungsten silicide films and that also determine the stoichiometry of the deposited films.

These and other objects of the present invention are achieved in a method for growing a thin tungsten silicide film on a hydrated substrate in a reaction space. A tungsten halide precursor, where the halide is not fluorine, is introduced into the reaction space to the hydrated substrate to create, for example, a chlorine terminated substrate surface and deposit tungsten without scavenging silicon. A silicon hydride precursor is then introduced into the reaction space to the chloride terminated substrate surface to create a hydride terminated substrate surface and deposit silicon. The two preceding steps are repeated an integral number of times to form a tungsten silicide film on the substrate, wherein a reaction by-product is a hydrogen halide.

In another embodiment of the present invention, a method for growing a thin film on a hydrated substrate in a reaction space introduces a tungsten halide precursor, where the halide is not fluorine, into the reaction space to the hydrated substrate to create a halide terminated substrate surface. SiH₂Cl₂ is then introduced into the reaction space to the halide terminated substrate surface to create a hydride terminated substrate surface. The two preceding steps are then repeated an integral number of times to form a metal silicide film on the substrate, wherein a reaction by-product is a hydrogen halide.

In another embodiment of the present invention, a method for growing a thin film on a hydrated substrate in a reaction space introduces a tungsten halide precursor, where the halide is not fluorine, into the reaction space to the hydrated substrate to create a halide terminated substrate surface. SiH₂Cl₂ is then introduced into the reaction space to the halide terminated substrate surface to create a hydride terminated substrate surface. Atomic hydrogen is then introduced into the reaction space to create a hydrogen terminated. The preceding three steps are then repeated an integral number of times to form a metal silicide film on the substrate, wherein a reaction by-product is a hydrogen halide.

In another embodiment of the present invention, a method for growing a thin film on a hydrated substrate in a reaction space introduces a tungsten halide, where the halide is not fluorine, into the reaction space to the hydrated substrate to create a halide terminated substrate surface. Atomic hydrogen is then introduced into the reaction space to the surface previously terminates with a halide. A silicon chloride precursor is introduced into the reaction space to the surface previously terminates with a halide. Then the chlorinated surface is hydrated using atomic hydrogen or silicon hydride. The preceding three steps are then repeated an integral number of times to form a metal silicide film on the substrate, wherein a reaction by-product is a hydrogen halide.

In other embodiment of the present invention, a method for growing a thin film on a hydrated substrate in a reaction space introduces a tungsten halide, where the halide is not fluorine, into the reaction space to the hydrated substrate to create a halide terminated substrate surface. Atomic hydrogen is then introduced into the reaction space to the surface previously terminates with a halide to create a hydrided surface. A silicon chloride precursor is introduced into the reaction space to the hydrogen terminated substrate surface to create a halide terminated substrate surface. Atomic hydrogen is then introduced into the reaction space to the surface previously terminates with a halide. The preceding four steps are then repeated an integral number of times to form a metal silicide film on the substrate, wherein a reaction by-product is a hydrogen halide.

In another embodiment of the present invention, a method for growing a thin film on a hydrated substrate in a reaction space introduces a first tungsten halide, where the halide is not fluorine, into the reaction space to the hydrated substrate to create a halide terminated substrate surface. Atomic hydrogen is then introduced into the reaction space to the surface previously terminates with a halide. A second tungsten halide, where the halide is not fluorine, is then introduced into the reaction space to the hydrated substrate to create a halide terminated substrate surface. The two preceding steps are then repeated an integral number of times. A silicon hydride is then introduced into the reaction space to the surface previously terminates with a halide. The preceding three steps are repeated an integral number of times.

In another embodiment of the present invention, a method for growing a thin film on a hydrated substrate in a reaction space introduces a tungsten halide precursor, where the halide is not fluorine, into the reaction space to the hydrated substrate to create a halide terminated substrate surface. Si hydride is then introduced into the reaction space to the surface previously terminated with a halide. Si halide is then introduced into the reaction space to the surface previously terminates with a hydride. The two preceding steps are then repeated an integral number of times. Si hydride is then introduced into the reaction space to the surface previously terminated with a halide. All of the preceding steps are then repeated an integral of number of times.

In another embodiment of the present invention, a method for growing a thin film on a hydrated substrate in a reaction space controllably deposits a metal silicide with an ALD process in a pre-determined number of ALD cycles to form a metal layer on the hydrated substrate. The metal layer is terminated with a halide to form a surface halided metal layer. A tungsten layer using WCl₆ ALD chemistry and H reduction is then controllably deposited. The preceding three steps are then repeated an integral number of times to form a nanolaminate of silicide and metal layers on the hydrated substrate.

In another embodiment of the present invention, a method for growing a thin film on a hydrated substrate in a reaction space controllably deposits a metal silicide with an ALD process in a predetermined number of ALD cycles to form a metal layer on the hydrated substrate. The metal layer is terminated with a halide to form a surface halided metal layer. Additional tungsten layers are then controllably deposited using WF₆ ALD chemistry with silicon hydride reduction. The preceding three steps are then repeated an integral number of times to form a nanolaminate of silicide and metal layers on the hydrated substrate.

### DETAILED DESCRIPTION OF THE PREFERRED EMBODIMENTS

In various embodiments of the present invention, methods for depositing WSiₓ ALD films are provided. WL₆ , where L is a halide other than fluorine, is used as the tungsten precursor and a variety of silicon precursors are used to deliver silicon into the films by self limiting surface reactions with the W—L surfaces that are left after the completion of the WL₆ reaction. In addition, W—L conversion into W—H by means of hydrogen atomic exposures is implemented to extend the variety of silicon precursors that can be used and to facilitate tunability of W incorporation.

Suitable silicon precursors, including but are not limited to silane (SiH₄), disilane (Si₂H₆), dichlorosilane (DCS, SiH₂Cl₂), hexachlorodisilane (Si₂Cl₆) and tetrachlorosilane (SiCl₄), and the like, provide silicon delivery. In one embodiment, the upper temperature limit is 600 ° C. to avoid loss of Si as SiL₂ volatile species but some more restrictions are applicable to avoid decomposition and spontaneous silicon deposition in the case of silane, disilane and dichlorosilane . All ALD reactions are driven and become irreversible by the generation of volatile HL.

In one preferred embodiment of the present invention, the ALD sequence is implemented using the following surface chemistry strategies (some of the chemical equations are not balanced for simplicity):

—H (surface)+WCl₆ —WCl₅+HCl —WCl₅+Si₂H₆ —WSiₓH_{y}+HCl —WSi—H+WCl₆ a.

—H (surface)+WCl₆ —WCl₅+HCl —WCl_{5+SiH}₄ —WSiHₓ+HCl —WSi—H+WCl₆ b.

—H (surface)+WCl₆ —WCl₅+HCl —WCl₅+SiH₂Cl₂ —WsiClₓH_{y}+HCl —WSiClₓ—H+WCl₆ . . . c.

—H (surface)+WCl₆ —WCl₅+HCl —WCl₅+SiH₂Cl₂ —WSiClₓH_{y}+HCl —WSiClₓ—H+H [symbol] —WSiHₓ+HCl WSiHₓ+WCl₆ d.

—H (surface)+WCl₆ —WCl₅+HCl —WCl₅+H [symbol] —WH₅+5HCl —WH₅+Si₂Cl₆ —WSiₓCl_{y}H_{z}+HCl —WSiₓCl_{y}H_{z}+WCl₆ e.

—H (surface)+WCl₆ —WCl₅+HCl —WCl₅+H [symbol] —WH₅+5HCl —WH_{5+Si}₂Cl₆ —WSiₓCl_{y}H_{z}+HCl —WSiₓCl_{y}H_{z}+H [symbol] —WSiₓH_{y}+HCl —WSiₓH_{y}+WCl₆ f.

—H (surface)+WCl₆ —WCl₅+HCl —WCl₅+H [symbol] —WH₅+5HCl —WH₅+SiCl₄ —WSiClₓH_{y}+HCl —WSiClₓH_{y}+WCl₆ g.

—H (surface)+WCl₆ —WCl₅+HCl —WCl₅+H [symbol] —WH₅+5HCl —WH₅+SiCl₄ —WSiClₓH_{y}+HCl —WSiClₓH_{y}+H [symbol] —WSiHₓ+HCl —WSiHₓ+WCl₆ h.

These sequences describe the fundamental process of implementing alternating W and Si deposition. They are suitable for the deposition of WₓSi_{y} suicides. For the purpose of depositing WₙₓSi_{my} materials where either or both n, m are not equal to 1, the elements are deposited in multiple sequences. For example: W is added into the sequence a by repeating:

—H (surface)+WCl₆ —WCl₅+HCl —WCl₅+H [symbol] W—H+HCl —W—H (surface)+WCl₆ i.

The final sequence of consecutive W deposition cycles is lacking the H [symbol] exposure so the surface remains W—Cl covered and ready to react with a silicon hydride precursor, e.g. disilane:

—WCl₅+Si₂H₆ —WSiₓH_{y}+HCl —WSi—H+WCl₆

Alternately, adding more silicon to the stoichiometry is realized by (for example for chemistry a):

—WCl₅+Si₂H₆ —WSiₓH_{y}+HCl —WSiₓH_{y}+SiCl₄ —WSi—SiClₓ+HCl —WSi—SiClₓ+Si₂H₆ —WSiₓH_{y}+HCl —WSiₓH_{y}+SiCl₄ j.

The final sequence of the Si deposition cycles is lacking the SiCl₄ exposure so the surface remains Si—H covered and ready to react with WCl₆:

—WSi—H+WCl₆

Given so many multiple combinations of implementing stoichiometry control only a limited example is presented here (above). However, it will be appreciated that all possible combinations are within the scope of the present invention. For example, the usage of Si₂Cl₆ instead of SiCl₄ in the above example is a variant but can provide an additional knob for stoichiometry tuning. Also, some finer tuning of stoichiometry can be achieved if SiCl₄ and Si₂Cl₆ are used in some alternating sequence.

Since achieving silicide as a completely mixed alloy requires submonolayer alternation of W deposition and Si deposition it can be difficult to employ WF₆ as an ALD precursor for the silicide.

However, some resistivity reduction is achieved if silicides and W will be deposited as nanolaminate structures of W and WSiₓ. In this case the film is built with alternating complete layers of WSiₓ and W. For example an alternating film of 1:3 layers of WSiₓ and W may be implemented to substantially reduce the resistance of the film. An alternative embodiment is an ALD sandwich of WSiₓ—W—WSiₓ where silicide is implemented at a thickness that is sufficient to stabilize the interface with silicon at the given thermal conditions of the process flow. WF₆ chemistries may be used to build the bulk of the W component provided that WF₆ is not applied on surfaces covered with silicon. By way of example, in the case of the 1:3 nanolaminate structure suggested above, the first layer of W that is deposited on top of the WSiₓ is carried with WCl₆ chemistries. However, once a complete layer of W is deposited, the next two layers of W can be employed with WF₆ chemistries without scavenging the silicon from the silicide because this silicon is already buried under a complete layer of W.

As explained above, stoichiometry tuning is further extended beyond the capability of a single reaction scheme by alternating sequences of the different a—h chemistries and stoichiometry modifications of the A—H chemistries. Additional fine tunability resides on the actual substrate temperature. In various embodiments of the present invention, WCl₆ is used in sequence with conventional silicon precursors. It will be appreciated that the embodiments of the present invention are not limited to specific silicon precursors described above. In various embodiments, silicon precursors selected from SiₙXₘYₖHₗ, where X and Y are halides, F, Cl, Br and I, and n, m, k and l are integers.

All sequences are interchangeable because they all end by preparing the surface to react with the common tungsten precursor WCl₆. The methods of the present invention can be practiced in a reaction chamber described in U.S. Pat. application, Ser. No. 09/470,279, filed Dec. 22, 1999, incorporated herein by reference.

The foregoing description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

What is claimed,

1. A method for growing a thin tungsten silicide film on a substrate in a reaction space, comprising:
(a) providing a hydrated substrate;
(b) introducing a tungsten halide precursor, where the halide is not fluorine, into the reaction space to the hydrated substrate to create, for example, a chlorine terminated substrate surface and deposit tungsten without scavenging silicon;
(c) introducing a silicon hydride precursor into the reaction space to the chloride terminated substrate surface to create a hydride terminated substrate surface and deposit silicon;
(d) repeating steps (b) and (c) an integral number of times to form a tungsten silicide film on the substrate, wherein a reaction by-product is a hydrogen halide.

2. The method of claim 1, wherein the temperature of the reaction space is maintained less than 600° C.

3. The method of claim 1, further comprising:
providing an inert purge after each (b) and (c) step.

4. A method for growing a thin film on a substrate in a reaction space, comprising:
(a) providing a hydrated substrate;
(b) introducing a tungsten halide precursor, where the halide is not fluorine, into the reaction space to the hydrated substrate to create a halide terminated substrate surface;
(c) introducing a silicon precursor selected from SiₙXₘYₖHₗ, where X and Y are halides and n,m,k,l are integers, into the reaction space to the halide terminated substrate surface to create a hydride terminated substrate surface;
(d) repeating steps (b) and (c) an integral number of times to form a metal silicide film on the substrate, wherein a reaction by-product is a hydrogen halide.

5. A method for growing a thin film on a substrate in a reaction space, comprising:
(a) providing a hydrated substrate;
(b) introducing a tungsten halide precursor, where the halide is not a fluorine, into the reaction space to the hydrated substrate to create a halide terminated substrate surface;
(c) introducing silicon precursor selected from SiₙXₘYₖHₗ, where X and Y are halides, and n,m,k,l are integers, into the reaction space to the halide terminated substrate surface to create a hydride terminated substrate surface;
(d) introducing atomic hydrogen into the reaction space to create a hydrogen terminated substrate;
(d) repeating steps (b), (c) and (d) an integral number of times to form a metal silicide film on the substrate, wherein a reaction by-product is a hydrogen halide.

6. A method for growing a thin film on a substrate in a reaction space, comprising:
(a) providing a hydrated substrate;
(b) introducing a tungsten halide, where the halide is not fluorine, into the reaction space to the hydrated substrate to create a halide terminated substrate surface;
(c) introducing atomic hydrogen into the reaction space to the surface previously terminates with a halide
(d) introducing a silicon chloride precursor into the reaction space to the surface previously terminated with a halide; and
(e) repeating steps (c), (b), (c) and (d) an integral number of times to form a metal silicide film on the substrate, wherein a reaction by-product is a hydrogen halide.

7. A method for growing a thin film on a substrate in a reaction space, comprising:
(a) providing a hydrated substrate;
(b) introducing a tungsten halide, where the halide is not fluorine, into the reaction space to the hydrated substrate to create a halide terminated substrate surface;
(c) introducing atomic hydrogen into the reaction space to the surface previously terminated with a halide to create a hydrided surface;
(d) introducing a silicon chloride precursor into the reaction space to the hydrogen terminated substrate surface to create a halide terminated substrate surface;
(e) introducing atomic hydrogen into the reaction space to the surface previously terminated with a halide; and
(f) repeating steps (b), (c,) (d), and (e) an integral number of times to form a metal silicide film on the substrate, wherein a reaction by-product is a hydrogen halide.

8. A method for growing a thin film on a substrate in a reaction space, comprising:
(a) providing a hydrated substrate;
(b) introducing a first tungsten halide, where the halide is not fluorine, into the reaction space to the hydrated substrate to create a halide terminated substrate surface;
(c) introducing atomic hydrogen into the reaction space to the surface previously terminated with a halide;
(d) introducing a second tungsten halide, where the halide is not fluorine, into the reaction space to the hydrated substrate to create a halide terminated substrate surface;
(e) repeating steps (c) and (d) an integral number of times
(d) introducing a silicon hydride into the reaction space to the surface previously terminates with a halide; and
(e) repeating steps (b), (c) and (d) an integral number of times.

9. A method for growing a thin film on a substrate in a reaction space, comprising:
(a) providing a hydrated substrate;
(b) introducing a tungsten halide precursor, where the halide is not fluorine, into the reaction space to the hydrated substrate to create a halide terminated substrate surface;
(c) introducing Si hydride into the reaction space to the surface previously terminated with a halide;
(d) introducing Si halide into the reaction space to the surface previously terminates with a hydride;
(e) repeating (c) and (d) an integral number of times
(f) introducing Si hydride into the reaction space to the surface previously terminated with a halide; and
(g) repeating steps (b) through (f) an integral of number of times.

10. A method for growing a thin film on a substrate in a reaction space, comprising:
(a) providing a hydrated substrate;
(b) controllably depositing a metal silicide with an ALD process in a predetermined number of ALD cycles to form a metal layer on the hydrated substrate;
(c) terminating the metal layer with a halide to form a surface halided metal layer;
(d) controllably depositing a tungsten layer using WCl₆ ALD chemistry with H reduction;
(e) repeating steps (b) (c) and (d) an integral number of times to form a nanolaminate of silicide and metal layers on the hydrated substrate.

11. A method for growing a thin film on a substrate in a reaction space, comprising:
(a) providing a hydrated substrate;
(b) controllably depositing a metal silicide with an ALD process in a predetermined number of ALD cycles to form a metal layer on the hydrated substrate;
(c) terminating the metal layer with a halide to form a surface halided metal layer;
(d) controllably depositing additional tungsten layers using WF₆ ALD chemistry with silicon hydride reduction; and
(e) repeating steps (b) (c) and (d) an integral number of times to form a nanolaminate of silicide and metal layers on the hydrated substrate.

12. A method for growing a thin film on a substrate in a reaction space, comprising:
(a) providing a hydrated substrate;
(b) controllably depositing a metal halide with an ALD process in a predetermined number of ALD cycles to form a metal layer on the hydrated substrate;
(c) introducing atomic hydrogen into the reaction space to the surface previously terminated with a halide to create a hydrided surface;
(d) controllably depositing silicon halide; and
(e) repeating steps (b) (c) and (d) an integral number of times to form a nanolaminate of silicide and metal layers on the hydrated substrate.

13. A method for growing a thin film on a substrate in a reaction space, comprising:
(a) providing a hydrated substrate;
(b) controllably depositing a metal halide with an ALD process in a predetermined number of ALD cycles to form a metal layer on the hydrated substrate;
(c) introducing atomic hydrogen into the reaction space;
(c) introducing a silicon halide into the reaction space;
(d) introducing atomic hydrogen into the reaction space; and
(e) repeating steps (b) (c). (d) and (e) an integral number of times to form a nanolaminate of silicide and metal layers on the hydrated substrate.
